(19) United States
(12) Patent Application Publication
(10) Pub. No.: US 2014/0236509 A1
(43) Pub. Date: Aug. 21, 2014

(54) APPARATUS FOR DETECTING FAULTS IN BATTERY SYSTEM

(71) Applicant: SAMSUNG SDI CO., LTD., Yongin-si (KR)

(72) Inventor: Jong-Hoon Kim, Yongin-si (KR)

(73) Assignee: SAMSUNG SDI CO., LTD., Yongin-si (KR)

(21) Appl. No.: 14/082,036

(22) Filed: Nov. 15, 2013

Related U.S. Application Data
(60) Provisional application No. 61/767,744, filed on Feb. 21, 2013.

(51) Int. Cl. G01R 31/36

(52) U.S. Cl. CPC G01R 31/3648; G01R 31/362
USPC 702/63

(57) ABSTRACT

An apparatus for detecting a fault in a battery system, the apparatus including: a voltage detector configured to receive a voltage signal from the battery system and to digitize the voltage signal to generate voltage data; a discrete wavelet transformer configured to receive the voltage data and to perform a discrete wavelet transformation of the voltage data to generate transformation data; a statistical processor configured to receive the transformation data and to process the transformation data to generate statistical data, the statistical data including an average value of the transformation data; and a fault diagnosing unit configured to detect the fault in the battery system based on the statistical data and to transmit a fault signal when the fault is detected.

### CROSS-REFERENCE TO RELATED APPLICATION

This application claims priority to and the benefit of U.S. Provisional Application No. 61/767,744, filed on Feb. 21, 2013 in the U.S. Patent and Trademark Office, the entire content of which is incorporated herein by reference.

### BACKGROUND

1. Field

Aspects of the present invention relate to an apparatus for detecting faults in a battery system.

2. Description of the Related Art

As problems such as the destruction of the environment, resource depletion, etc. have become more serious, interest in a system for storing energy and efficiently using the stored energy has increased. Also, there is increased interest in new generation energy, which is energy that is generated without causing pollution or with a minimal amount of pollution. An energy storage system refers to a system which connects a battery system storing energy (e.g., new generation energy and electric energy) and an existing grid system to each other.

When the energy storage system operates, faults may occur in the battery system due to unexpected errors. These faults disable normal operation of the energy storage system and affect the grid system connected to the energy storage system. Although the unexpected errors may not be completely prevented, an apparatus for detecting and diagnosing faults in the energy storage system in real time to rapidly restore the energy storage system to a normal state is desired.

### SUMMARY

According to one embodiment, there is provided an apparatus for detecting a fault in a battery system, the apparatus including: a voltage detector configured to receive a voltage signal from the battery system and to digitize the voltage signal to generate voltage data; a discrete wavelet transformer configured to receive the voltage data and to perform a discrete wavelet transformation of the voltage data to generate transformation data; a statistical processor configured to receive the transformation data and to process the transformation data to generate statistical data, the statistical data including an average value of the transformation data; and a fault diagnosing unit configured to detect the fault in the battery system based on the statistical data and to transmit a fault signal when the fault is detected.

The transformation data may include j levels of frequency component data, j being a positive real number, and the statistical processor may be configured to receive the j levels of frequency component data as the transformation data and to calculate absolute values of the j levels of the frequency component data to generate magnitude values of each of the j levels of the frequency component data.

The fault diagnosing unit may be configured to compare the magnitude values with a reference value to detect the fault and to detect the fault if at least one of the magnitude values is greater than the reference value.

The reference value may be set to an initialization reference value. Here, the statistical processor may be configured to: calculate an average of the magnitude values to generate the average value; multiply the average value by a scaler to generate a scaled value; compare the scaled value to the reference value; and set the reference value to the scaled value when the scaled value is greater than the reference value.

The scaler may be about 2 to about 5.

The apparatus may further include a maximum value extractor. Here, the statistics processor may be configured to calculate an average of the magnitude values to generate the average value, the maximum value extractor may be configured to: receive the magnitude values and the average value; calculate maximum values of the magnitude values of each of the j levels of the frequency component data corresponding to a first time period to generate maximum magnitude values; and calculate a maximum value of the average value corresponding to the first time period to generate a maximum average value, and the fault diagnosing unit may be configured to: receive the maximum magnitude values and the maximum average value; individually compare ratios of each of the maximum magnitude values to the maximum average value; and detect the fault if at least one of the ratios is greater than a threshold value.

The threshold value may be a value between about 2 and about 5.

The fault signal may include information corresponding to which of the j levels of frequency component data the fault was detected in or to a severity of the fault.

The voltage detector may be configured to digitize the voltage signal to generate the voltage data at a sample rate of about 1 sample per second to about 10 samples per second.

The discrete wavelet transformation may be based on a Daubechies 3 wavelet.

According to an embodiment of the present invention, there is provided a method for detecting a fault in a battery, the method including: receiving a voltage signal from a battery system; digitizing the voltage signal to generate voltage data; performing a discrete wavelet transformation on the voltage data to generate transformation data; processing the transformation data to generate statistical data, the statistical data including an average value of the transformation data; analyzing the statistical data to detect the fault; and transmitting a fault signal when the fault is detected.

The transformation data may include one or more frequency component data, the processing of the transformation data to generate the statistical data may include calculating absolute values of the one or more frequency component data, the statistical data may further include the absolute values, and the analyzing of the statistical data to detect the faults may include: comparing the absolute values with a reference value; and detecting the fault when at least one of the absolute values is greater than the reference value.

The method may further include initializing the reference value to a predetermined value.

The method may further include: calculating the average value based on the absolute values; scaling the average value by a scaler to generate a scaled average value; comparing the scaled average value with the reference value; and setting the scaled average value as the reference value when the scaled average value is greater than the reference value.

The transformation data may include one or more frequency component data, the processing of the transformation data to generate the statistical data may include: calculating absolute values of the one or more frequency component data, the statistical data may further include the absolute values; and calculating the average value based on the absolute values, the analyzing of the statistical data to detect the faults may include: calculating maximum absolute values of the absolute values corresponding to a first time period; calculating a maximum average value of the average value corresponding to the first time period; calculate ratios of the maximum absolute values to the maximum average value; and detecting the fault when at least one of the ratios exceeds a reference value.

According to an embodiment, there is provided an energy storage system including: a power conversion system configured to convert a first power to a second power; a battery system configured to store and supply the second power, the battery system including: a plurality of battery cells coupled together; a terminal coupled to a first battery cell of the battery cells; a switch coupled to the terminal and the power conversion system; and a battery management system including: a voltage detector configured to receive a voltage signal from the battery cells and to digitize the voltage signal to generate voltage data; a discrete wavelet transformer configured to receive the voltage data and to perform a discrete wavelet transformation of the voltage data to generate transformation data; a statistical processor configured to receive the transformation data and to process the transformation data to generate statistical data, the statistical data including an average value of the transformation data; and a fault diagnosing unit configured to detect a fault in the battery system based on the statistical data and to transmit a fault signal when the fault is detected. Here, the switch is configured to couple the battery cells with the power conversion system according to the fault signal.

The voltage signal may correspond to a voltage at the terminal or a cell voltage of one of the battery cells.

### BRIEF DESCRIPTION OF THE DRAWINGS

FIG. 1 is a block diagram illustrating an apparatus for detecting faults in a battery system according to an exemplary embodiment of the present invention.

FIG. 2 is a block diagram illustrating an apparatus for detecting faults in a battery system according to another exemplary embodiment of the present invention.

FIG. 3 is a graph illustrating a scale function and a wavelet function according to an exemplary embodiment of the present invention.

FIG. 4 is a block diagram illustrating discrete wavelet transformation from the viewpoint of filtering.

FIG. 5 is a view illustrating coefficients of a low pass filter (LPF) and a high pass filter (HPF) according to an exemplary embodiment of the present invention.

FIG. 6 is a view illustrating a process of decomposing voltage data through multi-resolution analysis of discrete wavelet transformation.

FIG. 7 is a view illustrating down-sampling.

FIG. 8 is a view illustrating frequency bands of approximate voltage data having an n^{th} level and detailed voltage data having first through n^{th} levels.

FIG. 9A is a graph illustrating voltage data provided to explain a method of detecting faults, according to an exemplary embodiment of the present invention.

FIGS. 9B through 9G are graphs illustrating low frequency component data of a fifth level and frequency component data D1 through D5 of first through fifth levels extracted from the voltage data of FIG. 9A through multi-resolution analysis of discrete wavelet transformation.

FIGS. 10A through 10C are graphs illustrating an operation of a statistical processor.

FIG. 11 is a table illustrating operations of a maximum value extractor and a fault diagnosing unit.

### DETAILED DESCRIPTION

Certain aspects and features of embodiments of the present invention are described with reference to the accompanying drawings, in which exemplary embodiments are shown. The invention may, however, be embodied in many different forms and should not be construed as being limited to the embodiments set forth herein.

The terminology used in the application is used only to describe the discussed embodiments and does not have any intention to limit the present invention. An expression in the singular includes an expression in the plural unless they are clearly different from each other in a context. In the application, it should be understood that terms, such as “include” and “have”, are used to indicate the existence of a certain feature, number, step, operation, element, part, or a combination of them without excluding in advance the possibility of or addition of one or more other features, numbers, steps, operations, elements, parts, or combinations of them. Although terms, such as “first” and “second”, may be used to describe various elements, the elements are not limited by the terms. The terms may be used to classify a certain element from another element.

Certain inventive aspects are described more fully with reference to the accompanying drawings, in which exemplary embodiments are shown. Like reference numerals in the drawings generally denote like elements, and thus, in some instances, their repeated description is omitted.

As used herein, the term “and/or” includes any and all combinations of one or more of the associated listed items. Expressions, such as “at least one of,” when preceding a list of elements, modify the entire list of elements and do not modify the individual elements of the list.

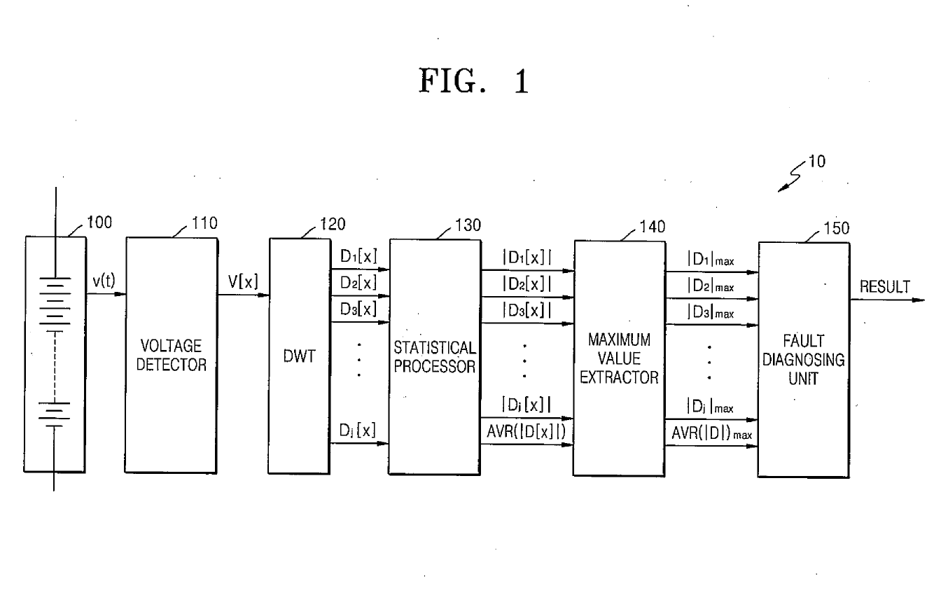

FIG. 1 is a block diagram illustrating an apparatus 10 for detecting faults in a battery system 100 according to an exemplary embodiment of the present invention.

Referring to FIG. 1, the apparatus 10 is connected to the battery system 100 and includes a voltage detector 110, a discrete wavelet transformer (DWT) 120, a statistical processor 130, a maximum value extractor 140, and a fault diagnosing unit 150.

The battery system 100 includes a battery that is supplied with electric energy from an external source to store the electric energy and that supplies the stored electric energy to externally connected electric loads.

The battery system 100 includes the battery, a protection circuit that protects the battery, and a battery management system that controls the protection circuit to protect the battery. For example, if an over-current or an over-discharge situation occurs, the battery management system may open a switch of the protection circuit to separate the battery from an input/output (I/O) terminal. The battery management system monitors a state of the battery (e.g., a temperature, a voltage, a current, etc. of the battery) to collect various types of data, such as voltage data, current data, and temperature data. The battery management system may perform cell balancing operations of battery cells according to the collected data and an internal algorithm. The apparatus 10 for detecting the faults in the battery system 100 may be included in the battery management system.

The battery system 100 may be a part of an energy storage system that is connected to a generation system and a grid system to stably supply power to a load. The energy storage system may store electric energy generated by the generation system in the battery or may supply the electric energy to the grid system, and may supply the electric energy stored in the battery to the grid system or store the electric energy supplied from the grid system in the battery. The energy storage system supplies the electric energy generated by the generation system or the electric energy stored in the battery to the load. For this purpose, the energy storage system includes a power conversion system (PCS), the battery system 100, a first switch, and a second switch.

The PCS includes power conversion apparatuses, such as an inverter, a converter, a rectifier, etc., and an integrated controller to convert electric energy provided from the generation system, the grid system, and/or the battery system 100 into appropriate electric energy and supply it to a place requiring the electric energy. The integrated controller may monitor states of the generation system, the grid system, the battery, and the load and may control the first switch, the second switch, the battery system 100, and the power conversion apparatuses according to an algorithm or a command of an operator. The apparatus 10 may be included in the integrated controller of the energy storage system.

According to the present embodiment, the voltage detector 110 receives a voltage v(t) from the battery system 100 and digitizes the voltage v(t) to generate and store voltage data V[x]. A sampling rate of the voltage detector 110 may be, for example, about 1 or about 10 times per second. However, the present invention is not limited thereto, and the sampling rate may be smaller than 1 or greater than 10 times per second.

The voltage v(t) may be a terminal voltage of an output terminal of the battery system 100. According to another example, the voltage v(t) may be a cell voltage of a particular battery cell of the battery system 100. The voltage v(t) has an analog value that changes according to a current profile input into or output from the battery system 100.

The voltage data V[x] has a digital value generated by digitizing the voltage v(t) varied according to a time t. The voltage data V[x] includes a set of the digital values defined according to a time x. The voltage detector 110 stores the voltage data V[x] during a period for determining whether the faults occur. Therefore, the voltage detector 110 may include an analog-to-digital converter (ADC) which converts the analog voltage v(t) into the digital voltage data V[x]. The voltage detector 110 may further include a memory which stores the generated digital voltage data V[x].

The DWT 120 performs discrete wavelet transformation with respect to the voltage data V[x] provided from the voltage detector 110 to generate frequency component data D₁[x], D₂[x], D₃[x], . . . and Dⱼ[x] (e.g., high frequency component data). In the present exemplary embodiment, the frequency component data D₁[x], D₂[x], D₃[x], . . . , and Dⱼ[x] of first through j^{th} levels are generated. Here, j is a natural number greater than 2.

The frequency component data D₁[x] of the first level may be data having the highest frequency band. The frequency component D₂[x] of the second level may be data having a lower frequency band than a frequency band of the frequency component data D₁[x] of the first level. The frequency component data Dⱼ[x] of the j^{th} level may be data having the lowest frequency band.

For example, if the frequency component data D₁[x] of the first level is data having a higher frequency band than a particular frequency f₀, the frequency component D₂[x] of the second level may be data having a higher frequency band than a frequency f₀/2, the frequency component data D₃[x] of the third level may be data having a frequency band lower than the frequency f₀/2 and higher than a frequency f₀/4, and the frequency component data Dⱼ[x] of the j^{th} level may be data having a frequency lower than a frequency f₀/2^{j-1} and higher than a frequency f₀/2^{j}.

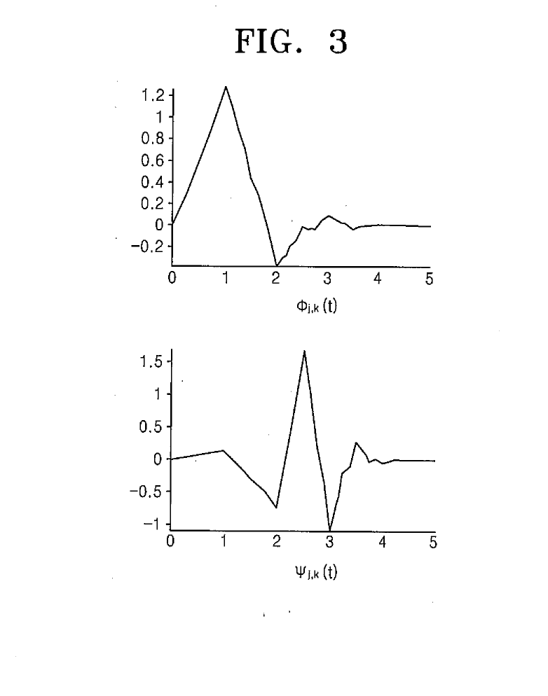

An exemplary discrete wavelet transformation will be described in detail later with reference to FIGS. 3 through 8.

The statistical processor 130 receives the frequency component data D₁[x], D₂[x], D₃[x], . . . , and Dⱼ[x] of the first through j^{th} levels generated by the DWT 120 to generate sizes |D₁[x]|, |D₂[x]|, |D₃[x]|, . . . , and |Dⱼ[x]| of the frequency component data D₁[x], D₂[x], D₃[x], . . . , and Dⱼ[x] of the first through j^{th} levels and an average AVR(|D[x]|) of the sizes |D₁[x]|, |D₂[x]|, |D₃[x]|, . . . , and |Dⱼ[x]|.

The statistical processor 130 removes negative and positive signs of the frequency component data D₁[x], D₂[x], D₃[x], . . . , and Dⱼ[x] of the first through j^{th} levels to generate the sizes |D₁[x]|, |D₂[x]|, |D₃[x]|, . . . , and |Dⱼ[x]| of the frequency component data D₁[x], D₂[x], D₃[x], . . . , and Dⱼ[x] of the first through j^{th} level. According to one embodiment, the sizes |D₁[x]|, |D₂[x]|, |D₃[x]|, . . . , and |Dⱼ[x]| are absolute values of the frequency component data D₁[x], D₂[x], D₃[x], . . . , and Dⱼ[x] of the first through j^{th} level.

The statistical processor 130 generates the average AVR(|D[x]|) of the sizes |D₁[x]|, |D₂[x]|, |D₃[x]|, . . . , and |Dⱼ[x]| of the frequency component data D₁[x], D₂[x], D₃[x], . . . , and Dⱼ[x] of the first through j^{th} level. The average AVR(|D[x]|) refers to an average of sizes of the frequency component data D₁[x], D₂[x], D₃[x], . . . , and Dⱼ[x] of the first through j^{th} level at the time x.

The maximum value extractor 140 receives the sizes |D₁[x]|, |D₂[x]|, |D₃[x]|, . . . , and |Dⱼ[x]| of the frequency component data D₁[x], D₂[x], D₃[x], . . . , and Dⱼ[x] of the first through j^{th} level and the average AVR(|D[x]|) generated by the statistical processor 130 and extracts maximum values of the sizes |D₁[x]|, |D₂[x]|, |D₃[x]|, . . . , and |Dⱼ[x]| and the average AVR(|D[x]|) to generate first, second, third, . . . , and j^{th} maximum values |D₁|ₘₐₓ, |D₂|ₘₐₓ, |D₃|ₘₐₓ, . . . , |Dⱼ|ₘₐₓ and a maximum average value AVR(|D|)ₘₐₓ.

The first maximum value |D₁|ₘₐₓ is the greatest value of the size |D₁[x]| of the frequency component data of the first level. For example, if the size |D₁[x]| of the frequency component data of the first level is greatest when x=x₁, the first maximum value |D₁|ₘₐₓ may be equal to |D₁[x₁]|.

The j^{th} maximum value |Dⱼ|ₘₐₓ is the greatest value of the size |Dⱼ[x]| of the frequency component data of the j^{th} level. For example, if the size |Dⱼ[x]| of the frequency component data of the j^{th} level is greatest when x=xⱼ, the j^{th} maximum value |Dⱼ|ₘₐₓ may be equal to |Dⱼ[xⱼ]|. Here, x₁ and xⱼ may be the same time or different times.

The maximum average value AVR(|D|)ₘₐₓ is the greatest value of the average AVR(|D[x]|). The time x for which the average AVR(|D[x]|) has the greatest value may be equal to one of times (e.g., x₁, x₂, x₃, . . . , and xⱼ) when the first through j^{th} maximum values |D₁|ₘₐₓ, |D₂|ₘₐₓ, |D₃|ₘₐₓ, . . . , and |Dⱼ|ₘₐₓ are generated or may be different from these times.

According to the present embodiment, the fault diagnosing unit 150 receives the first through j^{th} maximum values |D₁|ₘₐₓ, |D₂|ₘₐₓ, |D₃|ₘₐₓ, . . . , and |Dⱼ|ₘₐₓ and the maximum average value AVR(|D|)ₘₐₓ generated by the maximum value extractor 140 and compares the first through j^{th} maximum values |D₁|ₘₐₓ, |D₂|ₘₐₓ, |D₃|ₘₐₓ, . . . , and |Dⱼ|ₘₐₓ with the maximum average value AVR(|D|)ₘₐₓ to diagnose that the faults occur if a ratio exceeds a predetermined (or suitable) threshold value.

For example, the fault diagnosing unit 150 may compare a ratio of the first maximum value |D₁|ₘₐₓ to the maximum average value AVR(|D|)ₘₐₓ with the predetermined threshold value to diagnose that the faults occur if the ratio is greater than the predetermined threshold value. Here, the apparatus 10 detects a fault from the frequency component data D₁[x] of the first level. In other words, the apparatus 10 detects a component of a frequency band corresponding to the frequency component data D₁[x] of the first level as a fault.

The fault diagnosing unit 150 may compare a ratio of the second maximum value |D₂|ₘₐₓ to the maximum average value AVR(|D|)ₘₐₓ with the predetermined threshold value to diagnose whether a fault occurs. Also, the fault diagnosing unit 150 may compare a ratio of the j^{th} maximum value |Dⱼ|ₘₐₓ to the maximum average value AVR(|D|)ₘₐₓ with the predetermined threshold value to diagnose whether a fault occurs. The fault diagnosing unit 150 outputs fault detection diagnosis results as a signal RESULT.

The predetermined threshold value may vary according to a connection relation between the battery system 100 and batteries. For example, the predetermined threshold value may be one value between about 2 and about 5. For example, the predetermined threshold value may be 2.5.

According to one embodiment, if the ratios of the first through j^{th} maximum values |D₁|ₘₐₓ, |D₂|ₘₐₓ, |D₃|ₘₐₓ, . . . , and |Dⱼ|ₘₐₓ to the maximum average value AVR(|D|)ₘₐₓ are lower than the predetermined threshold value, the fault diagnosing unit 150 outputs a signal RESULT indicating that the faults do not occur. If any one of the ratios of the first through j^{th} maximum values |D₁|ₘₐₓ, |D₂|ₘₐₓ, |D₃|ₘₐₓ, . . . , and |Dⱼ|ₘₐₓ to the maximum average value AVR(|D|)ₘₐₓ is higher than the predetermined threshold value, the fault diagnosing unit 150 outputs a signal RESULT indicating that the faults occur.

The apparatus 10 according to the present embodiment diagnoses whether the faults occur according to the voltage v(t) output from the battery system 100. For example, if a high current flows into the battery system 100, the voltage v(t) output from the battery system 100 rapidly increases. The apparatus 10 decomposes the voltage v(t) into several frequency band components through multi-resolution analysis of the discrete wavelet transformation to accurately diagnose whether the faults occur.

The apparatus 10 may obtain information as to frequency component data from which a fault is detected, and thus, checks a cause of the fault. The apparatus 10 may detect the ratios of the first through j^{th} maximum values |D₁|ₘₐₓ, |D₂|ₘₐₓ, |D₃|ₘₐₓ, . . . , and |Dⱼ|ₘₐₓ to the maximum average value AVR(|D|)ₘₐₓ, and thus, determines a degree of seriousness of the fault.

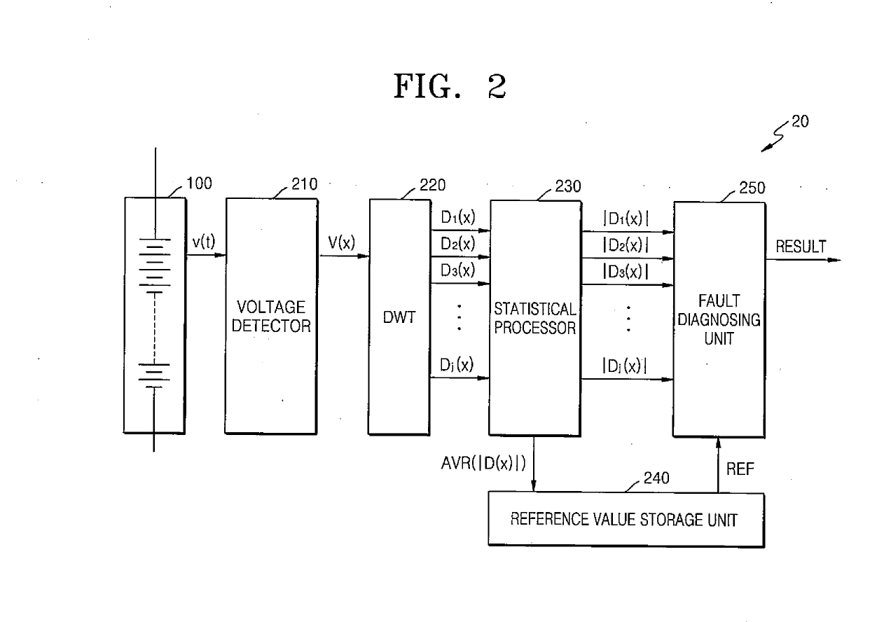

FIG. 2 is a block diagram illustrating an apparatus 20 for detecting faults in a battery system according to an exemplary embodiment of the present invention.

Referring to FIG. 2, the apparatus 20 is connected to a battery system 100 and includes a voltage detector 210, a DWT 220, a statistical processor 230, a reference value storage unit 240, and a fault detector 250.

The battery system 100 of FIG. 2 is equivalent to the battery system 100 of FIG. 1. The battery system 100 includes a battery that is supplied with electric energy from an external source, stores the electric energy, and supplies the stored electric energy to externally connected electric loads.

The voltage detector 210 receives a voltage v(t) from the battery system 100 and digitizes the voltage v(t) in real time to output voltage data V(x) according to a time x. A sampling rate of the voltage detector 210 may be about 1 to about 10 times per second. However, the present invention is not limited thereto, and thus, the sampling rate may be smaller than 1 or greater than 10 times per second.

The voltage v(t) may be a terminal voltage of the battery system 100 or a cell voltage of a particular battery cell of the battery system 100. The voltage data V(x) is a digital value generated by digitizing the voltage v(t) according to a time t, and x denotes a time.

The voltage detector 210 includes an analog-to-digital converter (ADC), which converts the analog voltage v(t) into the digital voltage data V(x) in real time.

The discrete wavelet transformer (DWT) 220 performs discrete wavelet transformation with respect to the voltage data V(x) generated by the voltage detector 110 to generate frequency component data D₁(x), D₂(x), D₃(x), . . . , and Dⱼ(x) having a plurality of levels.

The frequency component data D₁(x) of the first level may be data having the highest frequency band. The frequency component data D₂(x) of the second level may be data having a frequency band lower than the frequency band of the frequency component data D₁(x) of the first level. The frequency component data Dⱼ(x) of the j^{th} level may be data having the lowest frequency band.

According to the present embodiment, the statistical processor 230 receives the frequency component data D₁(x), D₂(x), D₃(x), . . . , and Dⱼ(x) of the first through j^{th} levels generated by the DWT 220 to generate sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels. Here, the statistical processor 230 generates an average AVR(|D(x)|) of the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels and provides the average AVR(|D(x)|) to the reference voltage storage unit 240.

The reference value storage unit 240 may store a reference value REF and may provide the reference value to the fault detector 250.

The fault detector 250 receives the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels from the statistical processor 230 and compares the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels with the reference value REF received from the fault detector 250 to detect whether faults occur, in real time.

According to the present embodiment, the fault detector 250 compares the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels with the reference value REF and detects that the faults occur if any one of the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels is greater than the reference value REF. The fault detector 250 outputs a signal RESULT indicating that the faults occur.

If the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels are all smaller than the reference value REF, the fault detector 250 outputs a signal RESULT indicating that the faults do not occur.

The sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels are values which are generated in real time from the voltage v(t) of the battery system 100 through the DWT 210 and the statistical processor 230. The fault detector 250 receives the sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels in real time and compares sizes |D₁(x)|, |D₂(x)|, |D₃(x)|, . . . , and |Dⱼ(x)| of the frequency component data D₁(x), D₂(x), D₃(x), . . . , and Dⱼ(x) of the first through j^{th} levels with the reference value REF to sense (e.g., immediately sense) whether or not the faults occur.

According to one embodiment, the reference value storage unit 240 stores an initial reference value REFᵢₙᵢ. Here, the reference value storage unit 240 outputs the initial reference value REFᵢₙᵢ as the reference value REF when the apparatus 20 initially operates. The initial reference value REFᵢₙᵢ may vary according to the battery system 100. For example, the initial reference value REFᵢₙᵢ may be a value between about 2 and about 5. For example, the initial reference value REFᵢₙᵢ may be about 2.5.

According to one embodiment, the reference value storage unit 240 receives the average AVR(|D(x)|) from the statistic processor 230. The reference value storage unit 240 may multiply the average AVR(|D(x)|) by a predetermined (or set) coefficient k to calculate a value kAVR(|D(x)|). According to another example, the statistical processor 230 may provide the value kAVR(|D(x)|) calculated by multiplying the average AVR(|D(x)|) by the predetermined coefficient k to the reference value storage unit 240.

The predetermined coefficient k may vary according to the battery system 100. For example, the coefficient k may be a value between about 2 and about 5. For example, the coefficient k may be about 2.5.

The reference value storage unit 240 may compare the value kAVR(|D(x)|) with the reference value REF and, if the value kAVR(|D(x)|) is greater than the reference value REF, may update the reference value REF as the value kAVR(|D(x)|). Here, because the reference value REF has the initial reference value REFᵢₙᵢ when the apparatus 20 initially operates, the reference value storage unit 240 compares the value (kAVR(|D(x)|) with the initial reference value REFᵢₙᵢ and, if the value kAVR(|D(x)|) becomes greater than the initial reference value REFᵢₙᵢ, updates the reference value REF as the value kAVR(|D(x)|). This updating process is performed in real time, and the reference value storage unit 240 stores the greater one of the initial reference value REFᵢₙᵢ and a value kAVR(|D|)ₘₐₓ calculated by multiplying a maximum value of the average AVR(|D(x)|) by the coefficient k as the reference value REF.

For example, if the initial reference value REFᵢₙᵢ and the coefficient k are each 2.5, and the average AVR(|D(x)|) is smaller than 1, the reference value REF is 2.5. If the average AVR(|D(x)|) is greater than 2.5, i.e., is 2.7, when x=x₁, the reference value REF is updated as 2.7. If the average AVR(|D(x)|) is greater than 2.7 when x=x₂, e.g., is 3.1, the reference value REF is updated as 3.1.

The apparatus 20 collects the voltage v(t) output from the battery system 100 to detect whether the faults occur, in real time. For example, if a high current flows into the battery system 100, the voltage v(t) output from the battery system 100 rapidly increases. Also, in one or more embodiments, the apparatus 20 decomposes the voltage v(t) into components of several frequency bands through multi-resolution analysis of the discrete wavelet transformation to detect that a peak greater than the reference value REF occurs in the component of the particular frequency band in order to sense that the faults occur, in real time.

The apparatus 20 may obtain information as to frequency component data from which a fault is detected, and thus, may check a cause of the fault. Also, the apparatus 20 may obtain information about a degree of seriousness of the fault through a peak value of the component of the particular frequency band.

An exemplary embodiment of a discrete wavelet transformation will now be described. A wavelet transform is used to convert a size and a horizontal position of a circular wavelet function to decompose a source signal x(t). A continuous wavelet transform (CWT) is defined as in Equation 1 below:

$${W}^{f} ( a , b ) = < x ( t ) , \\ {Ψ}_{a , b} ( t ) >= \frac{1}{\sqrt{a}} {\int }_{- ∞}^{∞} x ( t ) {Ψ}^{*} ( \frac{t - b}{a} ) d t \qquad ( 1 )$$

Here, a and b denote parameters respectively indicating a scale and a translation, ψ(t) denotes a wavelet analytic function, and ψ* denotes a complex conjugate function. The result of Equation 1 is a wavelet coefficient of the scale and translation parameters.

If a=2^{j} and b=k2^{j} are substituted into Equation 1, a discrete wavelet transform is defined as in Equation 2. Integers j and k are respectively scale and translation variables.

$${W}^{f} ( j , k ) = < x ( t ) , \\ {Ψ}_{j , k} ( t ) >= \frac{1}{\sqrt{{2}^{f}}} {\int }_{- ∞}^{∞} x ( t ) {Ψ}^{*} ( \frac{t - K {2}^{j}}{{2}^{j}} ) d t \qquad ( 2 )$$

A scale function φ and a wavelet function ψ are used in one-dimensional signal decomposition. The wavelet function ψ is used to obtain a detailed component Dⱼ from the source signal x(t), and the scale function φ is used to decompose an approximate component Aⱼ from the source signal x(t). FIG. 3 is a graph illustrating the scale function φ and the wavelet function ψ according to an exemplary embodiment of the present invention. The scale function φ and the wavelet function ψ shown in FIG. 3 are based on a Daubechies 3 (dB3) wavelet, as an example.

Approximate information xₐ^{j}(t) and detailed information x_{d}^{j}(t) obtained in an arbitrary scale j from the source signal x(t) in the DWT may be respectively represented as in Equation 3 below:

$$\begin{matrix}{x}_{a}^{j} ( t ) = {\sum }_{k}^{ } {a}_{j , k} {φ}_{k} ( {2}^{- j} t ) \\ = {\sum }_{k}^{ } {a}_{j , k} {φ}_{j , k} ( t ) , k ∈ Z\end{matrix} \\ \begin{matrix}{x}_{d}^{j} ( t ) = {\sum }_{k}^{ } {d}_{j , k} {ψ}_{k} ( {2}^{- j} t ) \\ = {\sum }_{k}^{ } {d}_{j , k} {ψ}_{j , k} ( t ) , k ∈ Z\end{matrix} \qquad ( 3 )$$

Here, a_{j,k} and d_{j,k} respectively denote an approximate coefficient (a scale coefficient) and a detailed coefficient (a wavelet coefficient).

The source signal x(t) may be expressed as in Equation 4 by using the approximate information xₐ^{j}(t) and the detailed information x_{d}^{j}(t).

$$x ( t ) = {\sum }_{k}^{ } {a}_{j , k} {2}^{- \frac{j}{2}} φ ( {2}^{- j} t - k ) + {\sum }_{j = 1}^{ } {\sum }_{k}^{ } {d}_{j , k} {2}^{- \frac{j}{2}} ψ ( {2}^{- f} t - k ) \qquad ( 4 )$$

Here, a_{j,k} and d_{j,k} may be expressed as in Equation 5 by using the scale function φ and the wavelet function ψ.

$${a}_{j , k} = < x ( t ) , \\ {φ}_{j , k} ( t ) >= {\int }_{r}^{ } x ( t ) {2}^{- \frac{j}{2}} {φ}^{*} ( {2}^{- j} t - k ) d t \\ {d}_{j , k} = < x ( t ) , \\ {ψ}_{j , k} ( t ) >= {\int }_{R}^{ } x ( t ) {2}^{- \frac{j}{2}} {ψ}^{*} ( {2}^{- j} t - k ) d t \qquad ( 5 )$$

The approximate information xₐ^{j}(t) corresponds to a scale function φ_{j,k}(t) that is a low frequency component, and the detailed information x_{d}^{j}(t) corresponds to a wavelet function ψ_{j,k}(t) that is a high frequency component. If the approximate information xₐ^{j}(t) is A, and the detailed information x_{d}^{j}(t) is D, a signal x(t) may be multi-resolution-decomposed into nth levels and expressed as in Equation 6:

x(t)=Aₙ+D₁+D₂+ . . . +Dₙ₋₁Dₙ (6)

If detailed information Dₙ is added to approximate information Aₙ, approximate information having a one level higher resolution is obtained. In other words, Aₙ₋₁=Aₙ+Dₙ. Also, x(t) may be expressed with A₁+D₁.

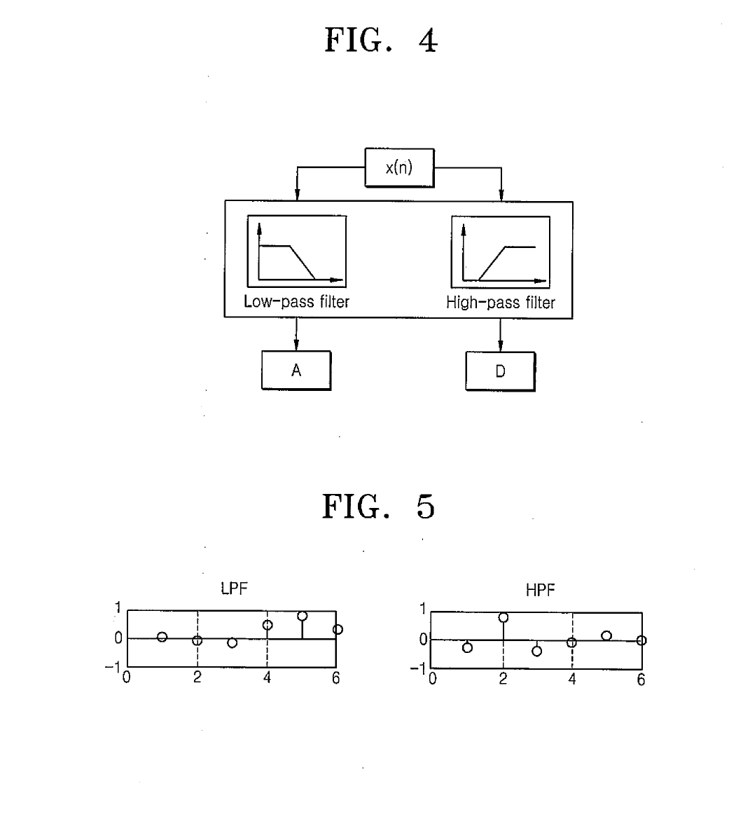

FIG. 4 is a block diagram illustrating a discrete wavelet transformation from the viewpoint of filtering.

Data x(n) in a discrete wavelet transform may be decomposed into approximate information A corresponding to a low frequency component and detailed information D corresponding to a high frequency component. A low pass filter (LPF) may be used to extract the approximate information A from the data x(n). A high pass filter (HPF) may be used to extract the detailed information D from the data x(n). The LPF and the HPF may not be real filters, which are realized physically or as circuits, but may be realized by data-processing.

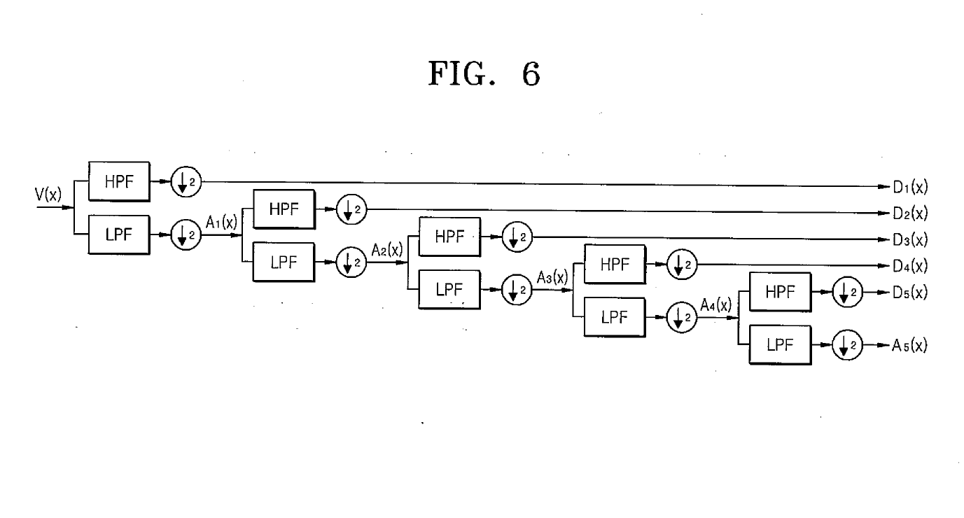

FIG. 5 is view illustrating coefficients of a LPF and a HPF, according to an exemplary embodiment of the present invention.

For example, as shown in FIG. 5, the coefficients of the LPF may be 0.0352, −0.0854, −0.1350, 0.4599, 0.8069, and 0.3327, and the coefficients of the HPF may be −0.3327, 0.8069, −0.4599, −0.1350, 0.0854, and 0.0352

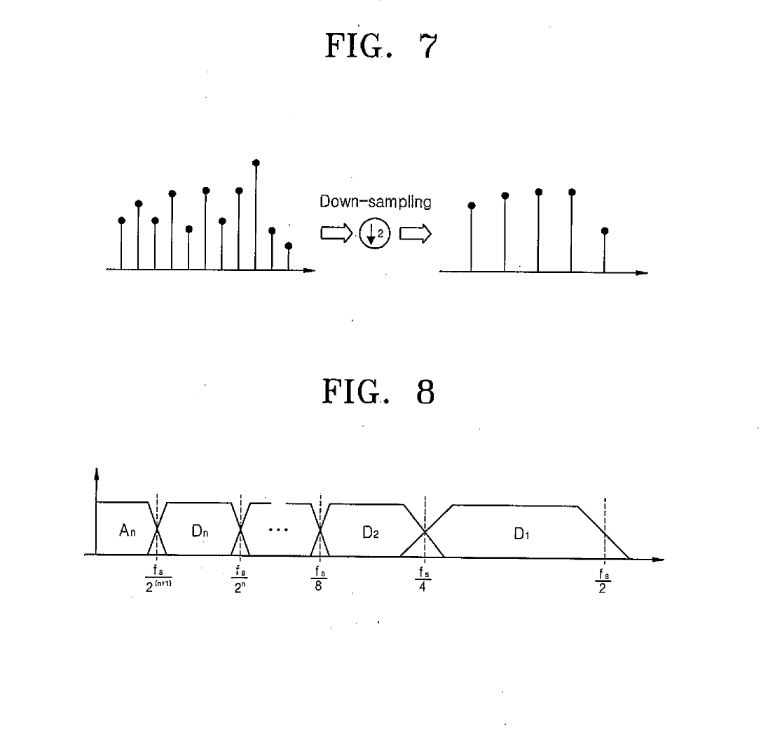

FIG. 6 is view illustrating a process of decomposing voltage data V(x) through multi-resolution analysis of discrete wavelet transformation. The discrete wavelet transformation is repeatedly performed five times in FIG. 6, but the number of repetitions of the discrete wavelet transformation is not limited thereto. For example, the discrete wavelet transformation may be performed one time or may be performed five or more times.

The voltage data V(x) is decomposed into approximate voltage data A₁(x) of a first level and detailed voltage data D₁(x) of a first level by using a first discrete wavelet transform and down-sampling. The approximate voltage data A₁(x) of the first level is decomposed into approximate voltage data A₂(x) of a second level and detailed voltage data D₂(x) of a second level by using a second discrete wavelet transform and down-sampling.

The approximate voltage data A₂(x) of the second level is decomposed into approximate voltage data A₃(x) of a third level and detailed voltage data D₃(x) of a third level by using a third discrete wavelet transform and down-sampling. The approximate voltage data A₃(x) of the third level is decomposed into approximate voltage data A₄(x) of a fourth level and detailed voltage data D₄(x) of a fourth level by using a fourth discrete wavelet transform and down-sampling. The approximate voltage data A₄(x) of the fourth level is decomposed into approximate voltage data A₅(x) of a fifth level and detailed voltage data D₅(x) of a fifth level by using a fifth discrete wavelet transform and down-sampling.

The detailed voltage data D₁(x), D₂(x), D₃(x), D₄(x), and D₅(x) of the first through fifth levels may be provided as frequency component data D₁(x), D₂(x), D₃(x), D₄(x), and D₅(x) of first through fifth levels to the statistical processor 130 or 230.

As shown in FIG. 6, the voltage data V(x) is expressed by using the approximate voltage data A₅(x) of the fifth level and the detailed voltage data D₁(x), D₂(x), D₃(x), D₄(x), and D₅(x) of the first through fifth levels. Also, approximate voltage data Aₙ₋₁(x) of an n−1^{th} level is expressed as a sum of approximate voltage data of an n^{th} level Aₙ(x) and detailed voltage data Dₙ(x) of an n^{th} level.

In the present example, the voltage data V(x) is recovered from the approximate voltage data A₅(x) of the fifth level and the detailed voltage data D₁(x), D₂(x), D₃(x), D₄(x), and D₅(x) of the first through fifth levels. This recovering process may be referred to as inverse discrete wavelet transformation (IDWT).

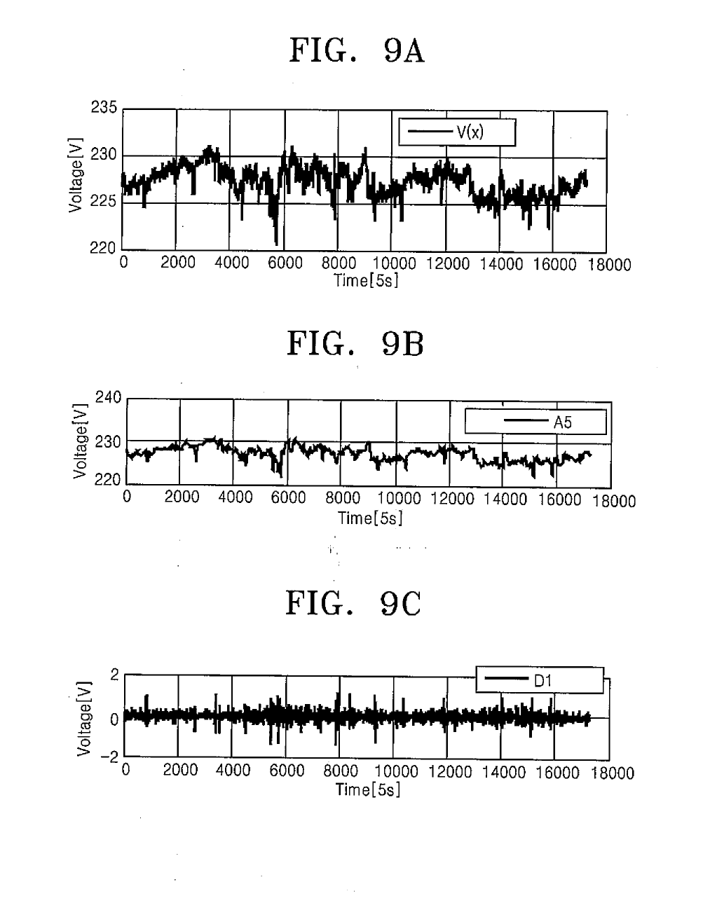

As shown in FIG. 6, if discrete wavelet transformation is repeated, a whole amount of data increases. This is because the voltage data V(x) is decomposed into approximate voltage data A(x) and detailed voltage data D(x). Therefore, after the discrete wavelet transformation is performed, down-sampling may be performed. The down-sampling is performed to select an even number or an odd number of approximate voltage data generated by a previous discrete wavelet transform and to remove unselected data. FIG. 7 is a view illustrating down-sampling. As shown in FIG. 7, n data is reduced to n/2 data through down-sampling.

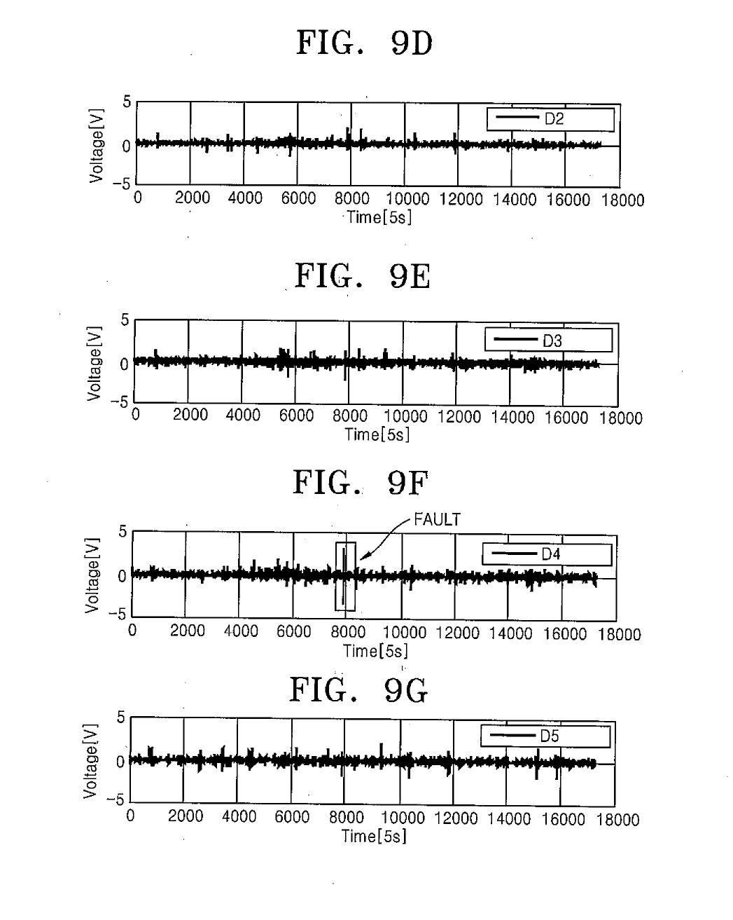

FIG. 8 is a view illustrating a frequency band of approximate voltage data Aₙ(x) of an n^{th} level and frequency bands of detailed voltage data D₁(x), D₂(x), . . . , and Dₙ(x) of first through n^{th} levels.

According to one embodiment, if the detailed voltage data D₁(x) of the first level is data having a frequency band smaller than a first frequency fₛ/2 and greater than a second frequency fₛ/4, the detailed voltage data D₂(x) of the second level corresponds to data having a frequency band smaller than the second frequency fₛ/4 and greater than a third frequency fₛ/8. The detailed voltage data D₃(x) of the third level corresponds to data having a frequency band smaller than the third frequency fₛ/8 and greater than a fourth frequency fₛ/16. Also, the detailed voltage data Dₙ(x) of the n^{th} level corresponds to data having a frequency band smaller than an n^{th} frequency fₛ/2ⁿ and greater than a n+1^{th} frequency fₛ/2ⁿ⁺¹. The approximate voltage data Aₙ(x)) of the n^{th} level corresponds to data having a frequency band smaller than the n+1^{th} frequency fₛ/2ⁿ⁺¹.

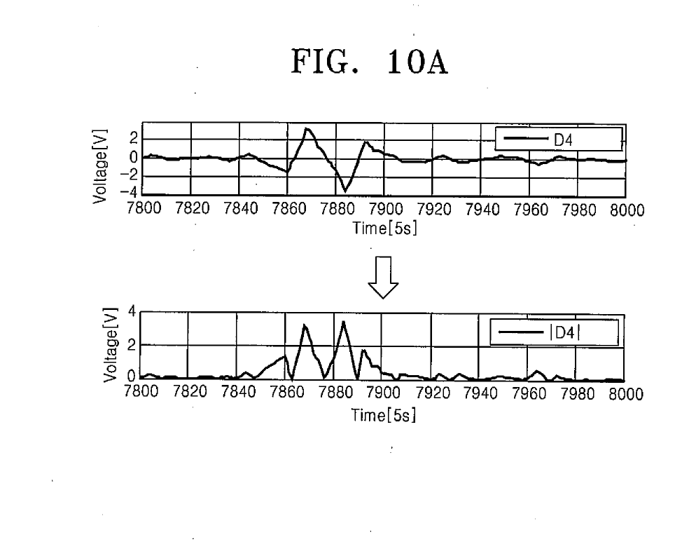

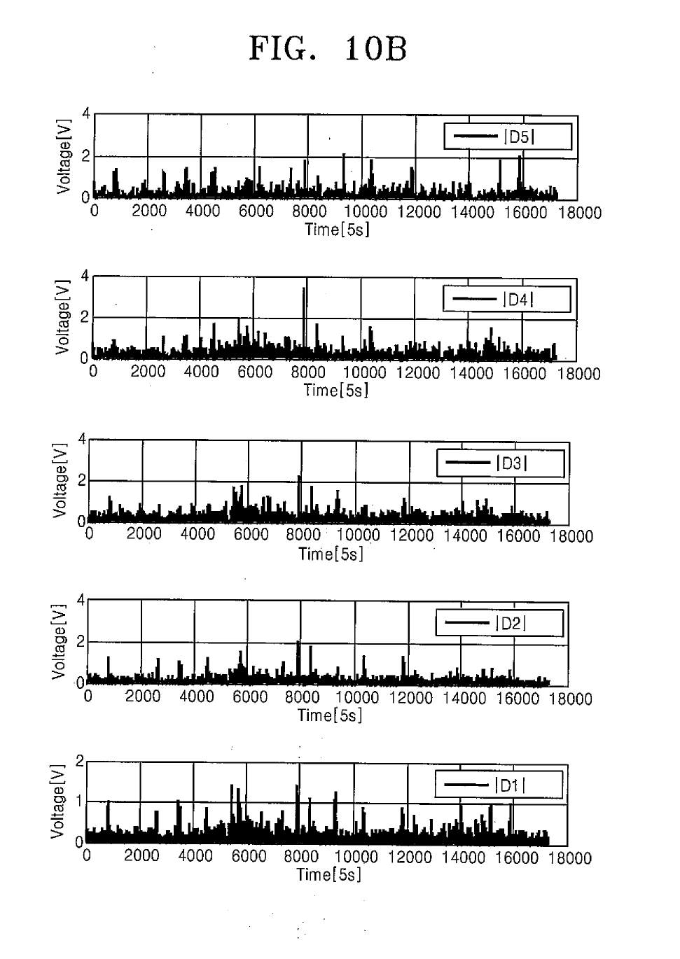

FIG. 9A is a graph illustrating voltage data V(x) provided to illustrate a method of detecting faults according to an exemplary embodiment of the present invention.

FIGS. 9B through 9G are graphs illustrating low frequency component data A5 of a fifth level and high frequency component data D1 through D5 of first through fifth levels extracted from the voltage data V(x) of FIG. 9A through multi-resolution analysis of discrete wavelet transformation.

Referring to FIG. 9A, the voltage data V(x) is exemplarily illustrated with respect to a time x.

Referring to FIGS. 9B through 9G, the low frequency component data A5 of the fifth level and the high frequency component data D1 through D5 of the first through fifth levels are extracted from the voltage data V(x) through the multi-resolution analysis of the discrete wavelet transformation.

The low frequency component data A5 of the fifth level is similar to the voltage data V(x), and high frequency component data is removed from the voltage data V(x). The low frequency component data A5 of the fifth level may be referred to as approximate voltage data of a fifth level.

The high frequency component data D1 through D5 of the first through fifth levels may have negative and positive values based on 0. According to one embodiment, if the high frequency component data D1 through D5 of the first through fifth levels are integrated with respect to a time, an integral value is 0.

If a charging time and a discharging time are short, e.g., charging and discharging are frequently alternately performed, values of the high frequency component data D1 through D5 increase as shown on the graphs. However, if the charging time and the discharging time are long, variations between charging and discharging may not appear in the high frequency component data D1 through D5.

If a high current rapidly flows into a battery system due to faults, it may be difficult to detect a rapid variation in the low frequency component data A5, but it may be easy to detect rapid variations in the high frequency component data D1 through D5.

In the illustrated embodiment, the high frequency component data D4 of the fourth level has a high peak at a time slightly faster than about 8000 differently from the other high frequency component data D1 through D3 and D5. The other high frequency component data D1 through D3 and D5 do not have high peaks at the same time, but the high peak is detected in the high frequency component data D4 of the fourth level, thereby indicating that a fault may have occurred. For example, if a size of a peak exceeds a predetermined normal, range, it is diagnosed that a fault occurred.

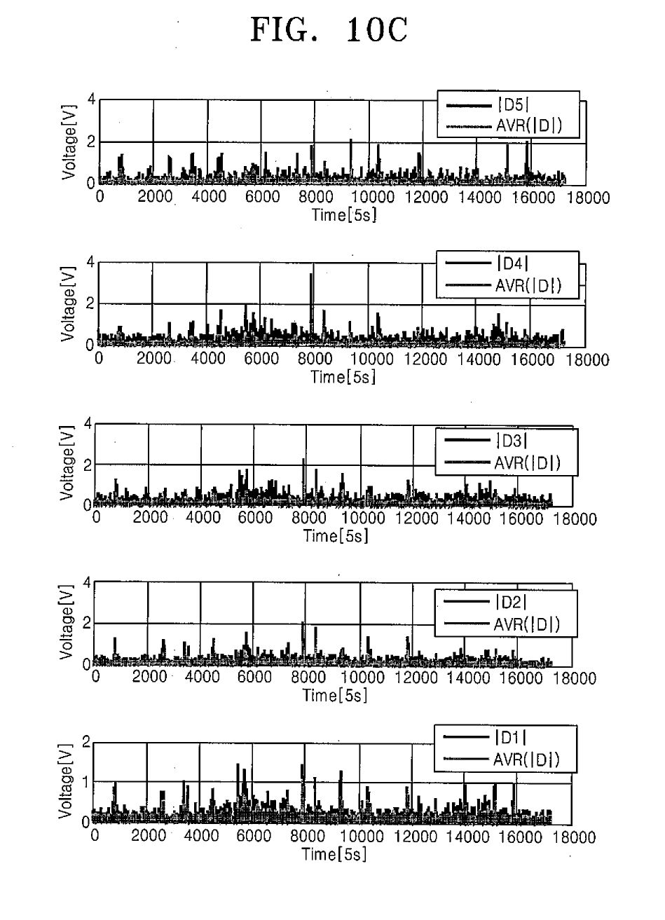

FIGS. 10A through 10C are graphs, illustrating an operation of a statistical processor 130.

Referring to FIG. 10A, the statistical processor 130 generates a size |D4| of high frequency component data of a fourth level from the high frequency component data D4 of the fourth level.

The size |D4| of the high frequency component data of the fourth level is generated by calculating an absolute value on the frequency component data of the fourth level. For example, data of the high frequency component data D4 of a fourth level having a negative value is converted into data having a positive value with the same size.

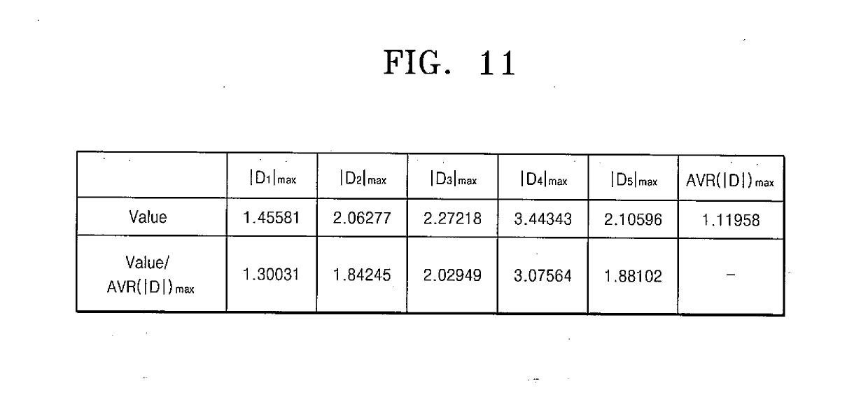

Referring to FIG. 10B, the statistical processor 130 generates sizes |D1| through |D5| of high frequency component data D1 through D5 of first through fifth levels. The graphs of FIG. 11B illustrating the sizes |D1|-|D5| of the high frequency component data D1 through D5 of the first through fifth levels are generated from the graphs of FIG. 10B illustrating the high frequency component data D1 through D5 of the first through fifth levels.

FIG. 10C illustrates an average AVR(|D|) and sizes |D1|-|D5| of high frequency component data of first through fifth levels generated by the statistical processor 130. The average AVR(|D|) is an average of the sizes |D1|-|D5| of the high frequency component data of the first through fifth levels and is generated by the statistical processor 130.

Referring to the second graph illustrating the size |D| of the high frequency component data of the fourth level and the average AVR(|D|), the size |D| of the high frequency component data of the fourth level has a much greater value than a maximum value of averages AVR(|D|) at around time x(=8000). The maximum value of the averages AVR(|D|) may be a criterion for determining a normal range indicating that the battery system 100 operates normally. For example, the size |D| of the high frequency component data of the fourth level has a value exceeding 3 times the maximum value of the average AVR(|D|). Here, if a threshold value is 2.5, a peak exceeding 3 times the maximum value of the averages AVR(|D|) occurs in the high frequency component data D4 of the fourth level. Therefore, an occurrence of a fault may be detected.

FIG. 11 is a table illustrating an operation of a maximum value extractor 140 and a fault diagnosing unit 150 according to an exemplary embodiment of the present invention.

Referring to FIG. 11, the maximum value extractor 140 extracts first through fifth maximum values |D₁|ₘₐₓ, |D₂|ₘₐₓ, |D₃|ₘₐₓ, |D₄|ₘₐₓ, and |D₅|ₘₐₓ from sizes |D1|-|D5| of high frequency component data of first through fifth levels. In the present exemplary embodiment, the first through fifth maximum values |D₁|ₘₐₓ, |D₂|ₘₐₓ, |D₃|ₘₐₓ, |D₄|ₘₐₓ, and |D₅|ₘₐₓ may be respectively 1.45581, 2.06277, 2.27218, 3.44343, and 2.10596.

The maximum value extractor 140 extracts an average maximum value AVR(|D|)ₘₐₓ from an average AVR(|D|). In the present exemplary embodiment, the average maximum value AVR(|D|)ₘₐₓ may be 1.11958.

The fault diagnosing unit 150 receives the first through fifth maximum values |D₁|ₘₐₓ, |D₂|ₘₐₓ, |D₃|ₘₐₓ, |D₄|ₘₐₓ, and |D₅|ₘₐₓ and the average maximum value AVR(|D|)ₘₐₓ from the maximum value extractor 140. The fault diagnosing unit 150 calculates ratios of the first through fifth maximum values |D₁|ₘₐₓ, |D₂|ₘₐₓ, |D₃|ₘₐₓ, |D₄|ₘₐₓ, and |D₅|ₘₐₓ to the average maximum value AVR(|D|)ₘₐₓ. According to the present exemplary embodiment, the ratios of the first through fifth maximum values |D₁|ₘₐₓ, |D₂|ₘₐₓ, |D₃|ₘₐₓ, |D₄|ₘₐₓ, and |D₅|ₘₐₓ to the average maximum value AVR(|D|)ₘₐₓ may be respectively 1.30031, 1.84245, 2.02949, 3.07564, and 1.88102.

Here, the fault diagnosing unit 150 determines whether the ratios are greater than a threshold value and, if any one of the ratios is greater than the threshold value, diagnoses that faults occur. Here, the threshold value may be 2.5.

Because the ratio of the fourth maximum value |D₄|ₘₐₓ to the average maximum value AVR(|D|)ₘₐₓ is 3.07564, which is greater than 2.5, the fault diagnosing unit 150 diagnoses that a fault occurs.

Certain non-limiting features and aspects have been described with reference to the figures. For conciseness of the specification, disclosure of conventional electronic configurations, control systems, software, and other functional aspects of the systems may be omitted. In addition, connections or connection members of lines between components shown in the drawings illustrate functional connections and/or physical or circuit connections, and the connections or connection members may be represented by replaceable or additional various functional connections, physical connections, or circuit connections in an actual apparatus. In some alternative embodiments, certain features and aspects may be omitted.

The ranges disclosed in the discussion above, include the individual values belonging to the ranges. For steps forming the methods described, the steps can be performed in an order not specifically described. The use of all illustrations or illustrative terms (e.g. for example, and so forth, etc.) in is simply to describe the aspects and principles, and the scope of the present invention is not limited by the illustrations or illustrative terms. In addition, it will be understood by those of ordinary skill in the art that various modifications, combinations, and changes can be made. Therefore, the present invention should not be limited to and defined by the embodiments described above.

What is claimed is:

1. An apparatus for detecting a fault in a battery system, the apparatus comprising:
a voltage detector configured to receive a voltage signal from the battery system and to digitize the voltage signal to generate voltage data;
a discrete wavelet transformer configured to receive the voltage data and to perform a discrete wavelet transformation of the voltage data to generate transformation data;
a statistical processor configured to receive the transformation data and to process the transformation data to generate statistical data, the statistical data comprising an average value of the transformation data; and
a fault diagnosing unit configured to detect the fault in the battery system based on the statistical data and to transmit a fault signal when the fault is detected.

2. The apparatus of claim 1,
wherein the transformation data comprises j levels of frequency component data, j being a positive real number, and
wherein the statistical processor is configured to receive the j levels of frequency component data as the transformation data and to calculate absolute values of the j levels of the frequency component data to generate magnitude values of each of the j levels of the frequency component data.

3. The apparatus of claim 2, wherein the fault diagnosing unit is configured to compare the magnitude values with a reference value to detect the fault, and to detect the fault if at least one of the magnitude values is greater than the reference value.

4. The apparatus of claim 3, wherein the reference value is set to an initialization reference value.

5. The apparatus of claim 4, wherein the statistical processor is configured to:
calculate an average of the magnitude values to generate the average value;
multiply the average value by a scaler to generate a scaled value;
compare the scaled value to the reference value; and
set the reference value to the scaled value when the scaled value is greater than the reference value.

6. The apparatus of claim 5, wherein the scaler is about 2 to about 5.

7. The apparatus of claim 2, further comprising a maximum value extractor,
wherein the statistics processor is configured to calculate an average of the magnitude values to generate the average value,
wherein the maximum value extractor is configured to:
receive the magnitude values and the average value;
calculate maximum values of the magnitude values of each of the j levels of the frequency component data corresponding to a first time period to generate maximum magnitude values; and
calculate a maximum value of the average value corresponding to the first time period to generate a maximum average value, and
wherein the fault diagnosing unit is configured to:
receive the maximum magnitude values and the maximum average value;
individually compare ratios of each of the maximum magnitude values to the maximum average value; and
detect the fault if at least one of the ratios is greater than a threshold value.

8. The apparatus of claim 7, wherein the threshold value is a value between about 2 and about 5.

9. The apparatus of claim 2, wherein the fault signal comprises information corresponding to which of the j levels of frequency component data the fault was detected in or to a severity of the fault.

10. The apparatus of claim 1, wherein the voltage detector is configured to digitize the voltage signal to generate the voltage data at a sample rate of about 1 sample per second to about 10 samples per second.

11. The apparatus of claim 1, wherein the discrete wavelet transformation is based on a Daubechies 3 wavelet.

12. A method for detecting a fault in a battery, the method comprising:
receiving a voltage signal from a battery system;
digitizing the voltage signal to generate voltage data;
performing a discrete wavelet transformation on the voltage data to generate transformation data;
processing the transformation data to generate statistical data, the statistical data comprising an average value of the transformation data;
analyzing the statistical data to detect the fault; and
transmitting a fault signal when the fault is detected.

13. The method of claim 12,
wherein the transformation data comprises one or more frequency component data,
wherein the processing of the transformation data to generate the statistical data comprises calculating absolute values of the one or more frequency component data, the statistical data further comprising the absolute values, and
wherein the analyzing of the statistical data to detect the faults comprises:
comparing the absolute values with a reference value; and
detecting the fault when at least one of the absolute values is greater than the reference value.

14. The method of claim 13, further comprising initializing the reference value to a predetermined value.

15. The method of claim 14, further comprising:
calculating the average value based on the absolute values;
scaling the average value by a scaler to generate a scaled average value;
comparing the scaled average value with the reference value; and
setting the scaled average value as the reference value when the scaled average value is greater than the reference value.

16. The method of claim 12,
wherein the transformation data comprises one or more frequency component data,
wherein the processing of the transformation data to generate the statistical data comprises:
calculating absolute values of the one or more frequency component data, the statistical data further comprising the absolute values; and
calculating the average value based on the absolute values,
wherein the analyzing of the statistical data to detect the faults comprises:
calculating maximum absolute values of the absolute values corresponding to a first time period;
calculating a maximum average value of the average value corresponding to the first time period;
calculate ratios of the maximum absolute values to the maximum average value; and
detecting the fault when at least one of the ratios exceeds a reference value.

17. An energy storage system comprising:
a power conversion system configured to convert a first power to a second power;
a battery system configured to store and supply the second power, the battery system comprising:
a plurality of battery cells coupled together;
a terminal coupled to a first battery cell of the battery cells;
a switch coupled to the terminal and the power conversion system; and
a battery management system comprising:
a voltage detector configured to receive a voltage signal from the battery cells and to digitize the voltage signal to generate voltage data;
a discrete wavelet transformer configured to receive the voltage data and to perform a discrete wavelet transformation of the voltage data to generate transformation data;
a statistical processor configured to receive the transformation data and to process the transformation data to generate statistical data, the statistical data comprising an average value of the transformation data; and
a fault diagnosing unit configured to detect a fault in the battery system based on the statistical data and to transmit a fault signal when the fault is detected,
wherein the switch is configured to couple the battery cells with the power conversion system according to the fault signal.

18. The energy storage system of claim 17, wherein the voltage signal corresponds to a voltage at the terminal or a cell voltage of one of the battery cells.
